(19) United States
(12) Patent Application Publication
(10) Pub. No.: US 2025/0005251 A1
(43) Pub. Date: Jan. 2, 2025

(54) EQUIVALENT WIRE CODES FOR ROUTING NETS IN AN INTEGRATED CIRCUIT DESIGN

(71) Applicant: INTERNATIONAL BUSINESS MACHINES CORPORATION, ARMONK, NY (US)

(72) Inventors: RAHUL M. RAO, BANGALORE (IN); MITHULA MADIRAJU, BANGALORE (IN)

(21) Appl. No.: 18/342,042

(22) Filed: Jun. 27, 2023

(51) Int. Cl. G06F 30/3953

(52) U.S. Cl. CPC G06F 30/3953

(57) ABSTRACT

A routing tool for routing nets within an integrated circuit design that includes: a processor; and a memory in communication with the processor and storing programming for the routing tool and a number of sets of equivalent wire codes. When the processor, alone or working with other processors, executes the programming, the routing tool routes each net in the integrated circuit design to satisfy parameters specified by a wire code associated with each net. Upon failure to route a net based on a current wire code assignment, the routing tool attempts to route the net using another wire code from a set of equivalent wire codes that includes the current wire code.

### BACKGROUND

Integrated circuits (ICs), also known as microchips or simply chips, are electronic devices that consist of a collection of interconnected electronic components fabricated onto a small semiconductor substrate, typically silicon. Integrated circuits are designed to perform specific functions, such as: processing, storing, and transmitting information. They are the building blocks of modern electronic devices and play a crucial role in various applications, ranging from consumer electronics to industrial systems.

Specifically, the miniaturization of ICs allows for the integration of numerous electronic components onto a single chip to enable the miniaturization of various electronic devices. This leads to smaller form factors, reduced power consumption, and improved portability. Integrated circuits can also provide higher performance, faster speed, and enhanced functionality compared to discrete components. They enable complex computations, data storage, and efficient signal processing. The mass production of Ics significantly reduces manufacturing costs compared to assembling circuits with individual components. This cost-effectiveness enables the widespread availability and affordability of electronic devices.

Ics also offer designers flexibility in implementing complex circuitry, allowing for customization, programmability, and integration of different functions on a single chip. This facilitates innovation and rapid development of new electronic systems.

### SUMMARY

According to an example of the present subject matter, a routing tool for routing nets within an integrated circuit design that includes: a processor; and a memory in communication with the processor and storing programming for the routing tool and a number of sets of equivalent wire codes. When the processor, alone or working with other processors, executes the programming, the routing tool routes each net in the integrated circuit design to satisfy parameters specified by a wire code associated with each net. Upon failure to route a net based on a current wire code assignment, the routing tool attempts to route the net using another wire code from a set of equivalent wire codes that includes the current wire code.

In various examples, one of the sets of equivalent wire codes includes wire codes with a reach within a specific tolerance but having varying track densities. Alternatively, one of the sets of equivalent wire codes includes wire codes with a track density within a specific tolerance but having varying reaches.

In various examples, the routing tool attempts to route the net using each wire code from the set of equivalent wire codes that includes the current wire code until the net is successfully routed. Alternatively, the routing tool attempts to route the net using different wire codes from the set of equivalent wire codes until a maximum trials limit is reached.

For example, the routing tool selects a wire code from the set of equivalent wire codes for the net based on hostility. The routing tool can prioritize routes for nets with an assigned wire code where the assigned wire code does not have any equivalent wire codes as specified by number of sets of equivalent wire codes. After assigning a new wire code to the net, the routing tool may update buffer voltage thresholds according to the new wire code.

In another general aspect, the following description explains a method of routing nets within an integrated circuit design process. The method includes: for a number of wire codes, computing a reach based on reach tables; for the number of wire codes, computing a track density; and, based on the reach and track density of each wire code, sorting the wire codes into a number of sets of equivalent wire codes, wherein a set of equivalent wire codes includes wire codes having a reach or track density that is within a certain corresponding tolerance. The number of sets of equivalent wire codes allows a routing tool additional options in routing a net according to any of the equivalent wire codes associated with a wire code of that net to produce a successful routing of the nets.

In another general aspect, the following description explains a computer program product having a non-transitory machine-readable storage medium incorporating instructions for a routing tool of an integrated circuit design system. For example, the instructions include: routing instructions for routing a net of an integrated circuit design using an initial wire code; instructions for selecting an equivalent wire code based on failure to route a net using the initial wire code; instructions for re-routing the net using the equivalent wire code; and instructions for detecting a successful routing of the net that satisfies criteria of either the initial wire code or the equivalent wire code.

### BRIEF DESCRIPTION OF THE DRAWINGS

FIG. 1 depicts a computing environment for the execution of a computer-implemented method or application, according to an example of the principles described herein.

FIG. 2 depicts the issues that can arise when the routing tool attempts to route a specified net.

FIG. 3 is a flowchart depicting a method of determining sets or buckets of equivalent wire codes.

FIG. 4 is a chart illustrating the determining of sets or buckets of equivalent wire codes.

FIG. 5 is a flowchart depicting the operation of a routing tool making use of sets or buckets of equivalent wire codes according to an example of the principles described herein.

FIG. 6 is a chart further illustrating the determining of sets or buckets of equivalent wire codes.

FIG. 7 is another flowchart depicting the operation of a routing tool making use of sets or buckets of equivalent wire codes according to another example of the principles described herein.

FIG. 8 is a chart depicting a computer program product of the new routing tool that makes use of sets or buckets of equivalent wire codes according to an example of the principles described herein.

### DETAILED DESCRIPTION

As noted above, an Integrated Circuit (IC) is built using circuit elements or components that are electrically interconnected into a circuit or circuits for performing a desired set of functions. Because ICs are typically mass-produced at great expense, the design of an IC before production must be rigorously engineered to avoid defects.

The basic process of designing an IC involves several stages and methodologies. Suites of software tools have been developed to support the highly complex steps of IC design. The initial step usually involves defining the specifications and requirements of the IC chip, including its functionality, performance goals, power constraints, and other design parameters. Then, at the Register Transfer Level (RTL) design stage, the behavior of the IC chip is described using a hardware description language (HDL) such as Verilog or VHDL. The RTL description captures the functional behavior of the design at a high level, specifying the flow of data and control between registers.

The RTL design is subjected to simulation using test vectors and verification tools. This helps ensure that the design functions correctly according to the specifications. Various verification techniques, such as linting, formal verification, and simulation-based testing, are employed to detect and resolve design issues. Then, RTL synthesis is the process of translating the RTL description into a gate-level representation. Synthesis tools map the RTL code to a library of standard cells, optimizing for area, power, and timing. The output is a gate-level netlist, representing the design in terms of logic nodes and their interconnections.

In the context of an IC, the term “net” refers to a representation for one of the electrical connections between two or more circuit elements or nodes. Each net has a unique name or identifier that distinguishes it from other nets in the design.

When a netlist is created, it includes a list of all the nets along with the nodes or pins that each net connects. The netlist specifies the connectivity of the circuit and provides the necessary information for simulating and analyzing the behavior of the design. Consequently, nets are essential for performing various IC design tasks, such as circuit simulation, timing analysis, and physical layout generation. They are also important for design verification, ensuring that the intended connections and signal paths are correctly implemented.

After the gate-level netlist is generated, it is used in a circuit simulation to verify that the circuit functions correctly. The gate-level simulation takes into account the actual gate delays, logic propagation, and interconnect delays of the synthesized design. Test vectors are applied to verify the correct operation of the gates and interconnections.

After successful simulation, floorplanning involves dividing the chip area into functional blocks and determining their placement. Power planning involves designing the power distribution network, ensuring sufficient power supply and minimizing power noise. The gate-level netlist is mapped onto the chip's floorplan, placing the individual gates, flip-flops, memory cells, and other components. Placement is optimized for performance, power, and area, aiming to minimize wire lengths and optimize signal routing.

A routing process then lays out the path of the interconnections or nets between circuit elements. Sophisticated routing tools have been developed for determining an optimal routing on a net-by-net basis. This routing step aims to meet timing requirements, minimize delays, and avoid congestion or crosstalk issues. Timing analysis is then performed to verify that the design meets the required timing specifications. This involves evaluating the critical paths and ensuring that the setup and hold times of flip-flops are met. If timing violations are detected, design modifications, such as buffer insertion or netlist changes, may be required.

Lastly, the layout is checked for adherence to design rules, such as minimum spacing, width, and other manufacturing constraints, using tools like Design Rule Checking (DRC) and Layout versus Schematic (LVS). Other physical verification steps, such as electrical rule checking (ERC) and design for manufacturing (DFM), are performed to ensure manufacturability. Once the design is physically verified and meets timing requirements, the final layout data is prepared for fabrication. The data, known as the “tape-out.” includes the various layers of the chip (such as metal, polysilicon, diffusion) along with their corresponding geometries and masks.

The following description focuses on the routing of connections (i.e., nets or interconnects) in the layout portion of the IC design process. As noted above, the timing of the interconnects or nets needs to meet the requirements of the functionality of the circuit. The timing of an interconnect refers to the propagation delay of signals traveling through the interconnect. Meeting timing constraints can be essential to the proper functioning of the integrated circuit.

Each net or interconnect will have a wire code assignment. The wire code specifies various parameters that should be met when the tagged net is routed, such as layer assignment and a width of the wire. Specifically, each net in the circuit design is assigned a specific layer on which it will be routed. In addition to assigning layers, the wire code assignment process also specifies the appropriate width of the wire for each net on its respective layer. The wire code assignment process also specifies the spacing of the net to neighboring nets. The wire width and spacing of the net affect the electrical characteristics and performance of the circuit. Steiner estimates are used to estimate the routing lengths and costs for the nets. These estimates help in predicting the overall timing behavior and slack (available timing margin) of the design. By considering the predicted slack gain, the wire code assignment can prioritize and optimize the routing of critical nets to improve overall performance.

Consequently, when the routing tool attempts to determine the layout or routing of all the interconnects, the routing tool seeks to satisfy the wire code assigned to each net in routing the net. Thus, the goal of wire code assignment is to optimize the routing of the nets in order to meet various design criteria, such as timing constraints, congestion, and available resources.

In order to meet timing criteria, the wire code assignment and routing process may involve promoting certain nets to a different metal layer. In the multiple layers of the metal stack of an IC, the lowest layer (closest to the device) has slower interconnects but is capable of providing a higher wiring density. Alternatively, the highest layer (closest to the packaging) provides faster interconnects, but has lower wiring density. By moving an interconnect to a higher layer, the signal propagation delay can be reduced, as the higher layers typically have lower resistance and capacitance, leading to faster signal transmission.

However, space and other limitations require a careful selection of which nets are promoted. Congestion refers to the situation where a particular layer or region of the design becomes heavily occupied with routing resources, leading to difficulties in achieving efficient and reliable routing. The wire code assignment process considers congestion as a constraint, ensuring that the assigned wire codes do not worsen congestion in critical areas.

Thus, layer promotion is performed while adhering to various design constraints, such as metal density limits, signal integrity requirements, and manufacturing considerations. The iterative nature of integrated circuit design allows designers to refine the placement, routing, and layer assignment of interconnects to meet the timing requirements. Through iterations of synthesis, placement, and routing, timing analysis is performed, and adjustments are made to improve the timing characteristics of the design.

The term “cheating,” as in layer cheating or wire code cheating, refers to using parameters in designing and routing the nets that are somewhat outside the established design constraints. Such cheating involves risks that the resulting design will not be viable, the risks increasing with the number of cheats used or the variance away from the established design constraints.

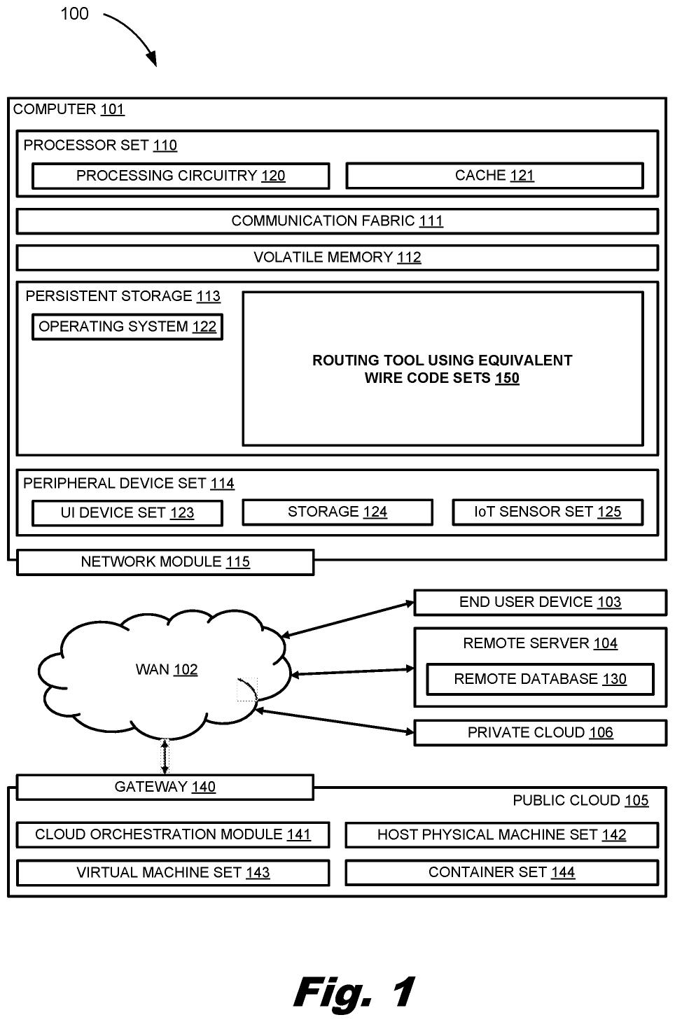

The following description describes a new routing tool for IC design. The new routing tool uses groups or sets of wire codes that are determined to be equivalent for design purposes. Consequently, if the routing tool attempts to route a net and cannot meet the parameters of the wire code originally assigned to that net, the routing tool can try assigning any of the equivalent wire codes, or each equivalent wire code in succession, to find a workable wire code assignment for the net that avoids or minimizes the risks typically associated with cheating to route a net only with respect to the original wire code assignment. This minimizes slack differences between the pre-route planning for each net and the post-route design for each net. FIG. 1 illustrates a computer architecture supporting the new routing tool 150.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse or any given order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As used in the present specification and in the appended claims, the term “a number of” or similar language is meant to be understood broadly as any positive number including 1 to infinity.

Turning now to the figures, FIG. 1 depicts a computing environment 100 for the execution of a new routing tool 150 that makes use of equivalent wire code sets, according to an example of the principles described herein.

Computing environment 100 contains an example of an environment for the execution of at least some of the computer code involved in performing the inventive methods, an application to provide context specific recommendations to producers regarding the satisfaction of their users. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

The EUD 103 may be a client device operated by a producer of services or products that wants an analysis of available user data to ascertain user satisfaction. Operation of the EUD 103 for this objective will be described in further detail below.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

As described further below, the EUD 103 may use the network 102 to access an application on remote server 104. The application will access, again using the network 102, available user data. The application will then analyze the user data, with context specific analysis, to ascertain user satisfaction and generate recommendations for the producer based on the analysis.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

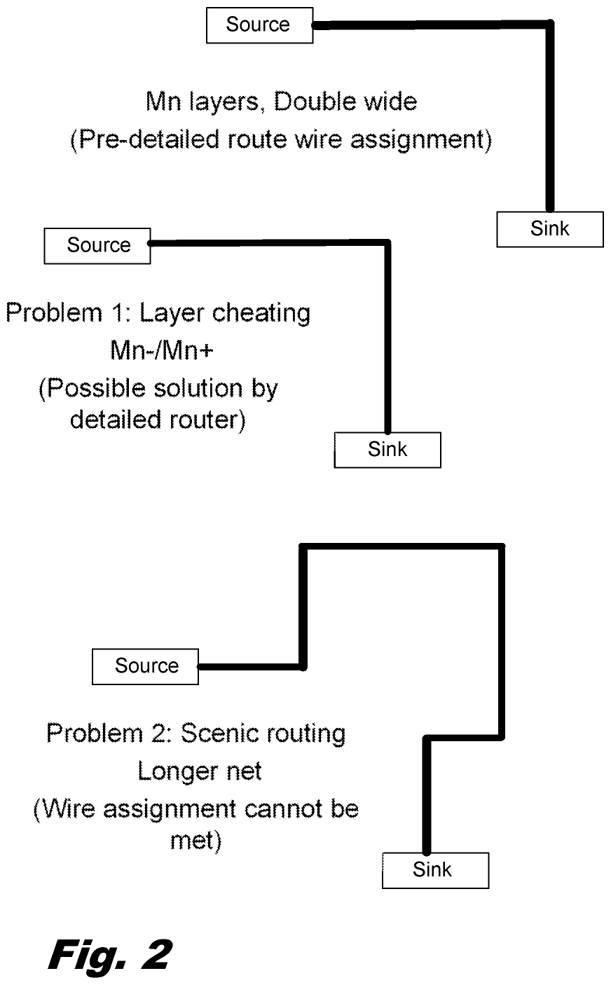

FIG. 2 depicts the issues that can arise when the routing tool attempts to route a specified net. As described above, each net has an associated wire code with parameters that should be met when routing and laying out that net. If the net is placed by the routing tool in a way that meets the wire code requirements, the net should function as expected, including as to timing, within the IC design. However, considering all the circuit elements and interconnecting nets of an IC, it can be difficult or impossible to route and layout a net in a way that meets all the requirements of the wire code assigned to that net.

FIG. 2 depicts some of the issues that may arise when a routing tool attempts to route a net. In the upper portion of the drawing, an ideal routing and layout of a net between a source and sink is shown. However, as the routing tool encounters issues in providing this configuration, the routing tool may engage in cheating to accommodate the net. This is shown in the center of the figure where layer cheating, moving the net to a higher or lower layer, has been tried as a possible solution by the routing tool. Alternatively, to accommodate other elements in the IC design, the routing tool may add length and legs to the net in what is referred to as a “scenic routing” because of the longer signal path. This is shown in the lower portion of FIG. 2. Scenic routing will add resistance and potentially other issues to the signal path that may negatively impact timing or other parameters making the routing non-viable.

Where any of these or other issues are encountered by the routing tool, the tool described here has the option of potentially changing the wire code and associated requirements assigned to the net that the tool is trying to route. Specifically, a set or sets of wire codes are determined that are considered to be equivalent for routing purposes. The routing tool can then assign a new equivalent wire code to the net under consideration to see if the net can then be routed successfully.

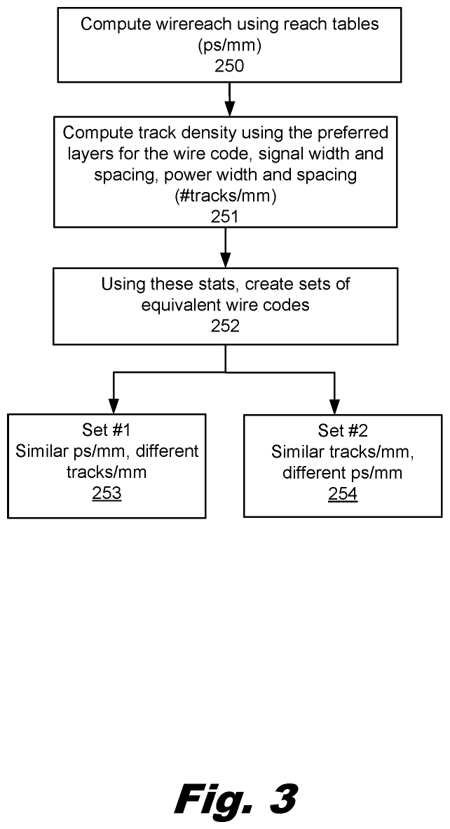

FIG. 3 is a flowchart depicting a method of determining sets or buckets of equivalent wire codes. This method may be a function of a routing tool, as described herein, or may be performed by a separate module supporting the routing tool.

As shown in FIG. 3, the method utilizes reach tables. Reach tables and the methods for computing them are established in the field of IC design. Specifically, reach tables are used in integrated circuit (IC) design and wire routing to determine the allowable dimensions and spacing between different circuit elements, such as wires, transistors, and other components, to ensure proper functionality and manufacturability. Thus, reach tables provide guidelines for the minimum and maximum dimensions of various circuit elements. These dimensions include parameters like wire widths, spacing between wires, transistor dimensions, and other critical features. Reach tables are typically based on the process technology used for manufacturing the ICs and take into account the limitations of the fabrication process.

The reach tables help designers ensure that the circuit elements meet certain design rules and constraints. For example, the minimum wire width and spacing guidelines ensure that the wires can carry the required electrical signals without significant resistance or crosstalk. The transistor dimensions specified in the reach tables ensure that the transistors can switch on and off properly and provide the desired performance characteristics. By following the reach tables, designers can ensure that their IC designs are manufacturable within the limitations of the fabrication process and that the resulting circuits will function properly. Deviating from the reach table guidelines may lead to manufacturing issues, yield loss, or performance degradation.

As shown in FIG. 3, the method begins by computing wire reach 250 based on the reach tables. Wire reach, also known as wirelength reach, refers to the maximum distance that a wire can be routed between two points in an integrated circuit (IC) layout. It is a design constraint that limits the length of the interconnects between circuit elements. Wire reach is an important consideration in IC design because longer interconnects can introduce signal delay, power consumption, and noise issues. The longer the wire, the higher the resistance and capacitance it exhibits, which can degrade signal integrity and increase power consumption. Excessive wirelength can also lead to delays in signal propagation, affecting the overall performance of the circuit. To optimize circuit performance, minimize power consumption, and meet timing requirements, IC designers strive to keep wire reaches within specified limits defined by design rules and guidelines provided by the semiconductor manufacturing process. Wire reach may be quantified in terms of signal speed as in picoseconds per millimeter (ps/mm).

After the computing wire reach, the method computes track density 251. This is done using the preferred layers and other parameters from the wire code for the net under consideration, e.g., signal width and space, power width and spacing, etc. Track density is quantified by the number of tracks per millimeter (#tracks/mm).

Using the wire reach and track density calculations, the method creates sets or buckets of wire codes that are considered to be equivalent 252. In the example of FIG. 3, two sets are created. The first set 253 is a group of wire codes that are similar as to reach (ps/mm) but have varying track density (tracks/mm). The second set 254 is a group of wire codes tha are similar in track density, but have varying reach.

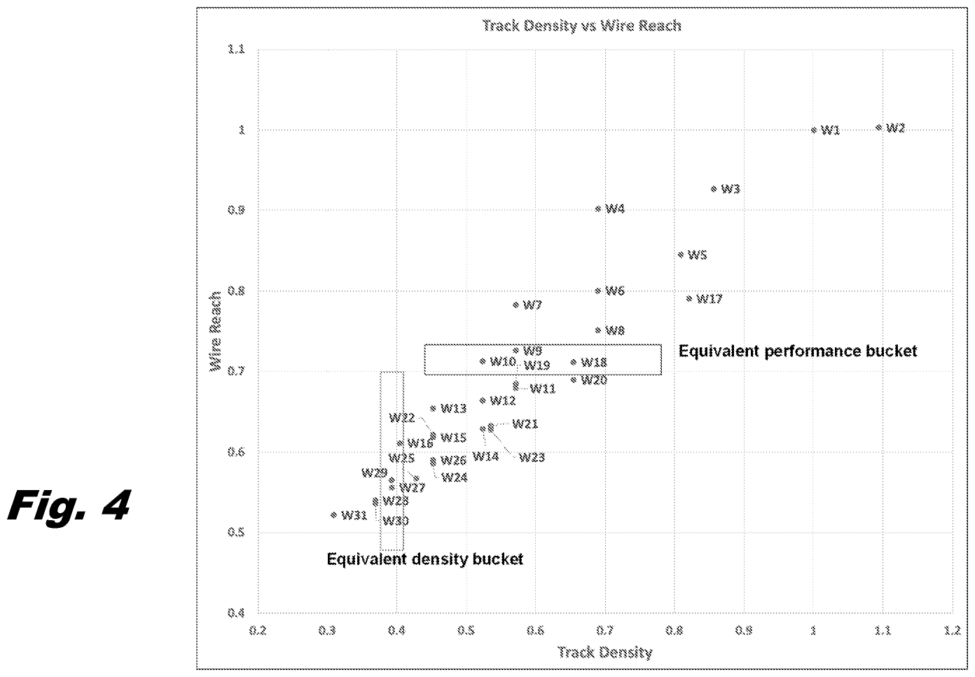

FIG. 4 is a chart illustrating the determining of sets or buckets of equivalent wire codes. Each technology will have a set of wire codes. Each wire code will have a different reach (ps/mm) and track density (tracks/mm). In FIG. 4, the population of wire codes are plotted as to reach (ps/mm) on the vertical axis versus track density (tracks/mm) on the horizontal axis.

The box on the lower left takes in a number of wire codes that are vertically aligned, meaning that they have the same or similar track density, but different values of wire reach. Consequently, all the wire codes in the box constitute a group of wire codes that are considered equivalent. The size of the box or the tolerance within which wire codes are considered equivalent can be set by a designer based on the considerations of a particular design process.

The box on the upper right encompasses two wire codes with similar wire reach (ps/mm), but different wire density (tracks/mm). Accordingly, these wire codes also constitute a group considered equivalent for use by the routing tool.

Two examples of the use of sets or buckets of equivalent wire codes can be generalized as follows:
#1 Similar reach (ps/mm), different track density (tracks/mm)
   First Set of Equivalent Wire Codes: Wire codes A, B, C
   Second Set of Equivalent Wire Codes: Wire codes D, E, F

In this example, during detailed routing, a net can be switched from wire code A to B without impacting performance if there is congestion for using A that might make the net scenic or create noise or Design Rule Check (DRC) issues.
#2 Similar track density (tracks/mm), different reach (ps/mm)
   First Set of Equivalent Wire Codes: A, E
   Second Set of Equivalent Wire Codes: B, D
   Third Set of Equivalent Wire Codes: C, F

In this example, during detailed routing, a net can be switched from wire code A to E without losing on tracks and without impacting performance (for example, during uplayering)

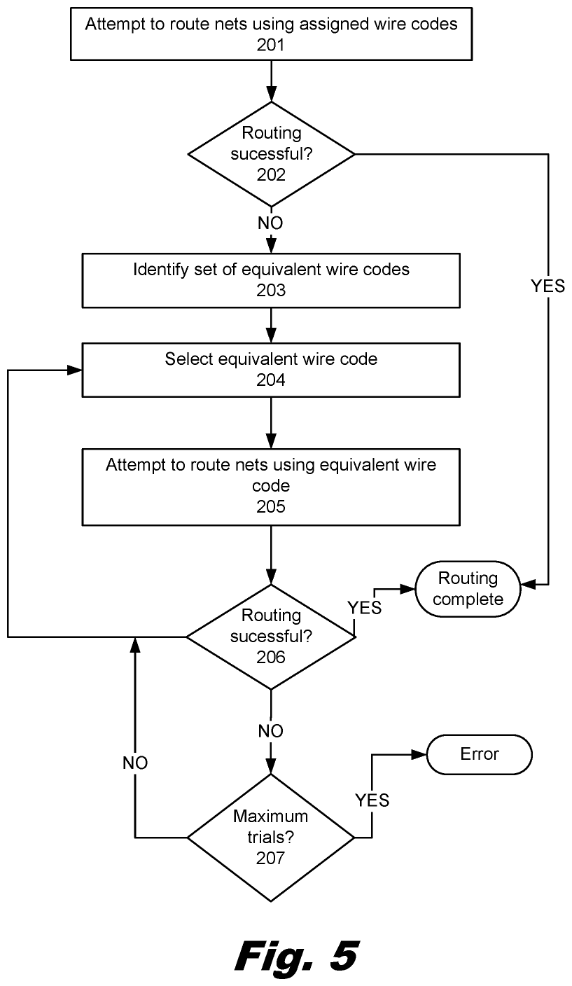

FIG. 5 is a flowchart depicting the operation of a routing tool making use of sets or buckets of equivalent wire codes according to an example of the principles described herein. As shown in FIG. 5, the method begins with the routing tool attempting to route the nets using the originally-assigned wire codes 201. If the routing tool is able to successfully route the nets while satisfying the original wire code assignments 202, the routing is complete.

However, if the routing cannot be completed while satisfying the original wire code assignment 202, the routing tool has the option of trying equivalent wire codes as described herein. The original assignment to each net may be a specific wire code from within a set of equivalents or the net may simply be assigned to the set of equivalent wire codes without specifying a particular initial wire code.

As noted above, each wire code includes a variety of parameters that are to be met with routing a net. If routing is unsuccessful, there is some condition that prevents a net from being routed in a way that meets all the specified parameters of its wire code. By changing the wire code assignment of the net to a different wire code, new wire code parameters are now under consideration which the routing tool may be able to satisfy.

Thus, as shown in FIG. 5, if routing is unsuccessful 202, the routing tool can identify or access sets of equivalent wire codes 203. The equivalency of wire codes is determined as described above and may be based on similar reach, track density or other parameters. As noted above, the routine to establish sets of equivalent wire codes can be a routine of the routing tool, can be a function of a separate module supporting the routing tool or could be manually specified by a designer.

The routing tool will select an equivalent wire code 204 for the net under consideration from the set of equivalent wire codes. The routing tool will then attempt to route the net using the equivalent wire code 205. If this routing is now successful 206, then routing is complete. If the routing is still unsuccessful 206, e.g., does not meet the criteria of the new wire code 205, the routing tool may select another of the equivalent wire codes from the set and try again 204, 205.

The routing tool could be configured to try every possible equivalent wire code available. Alternatively, the routing tool may be configured with a maximum number of trials 207. When the maximum number of trials has been reached without a successful routing, the routing tool returns an error.

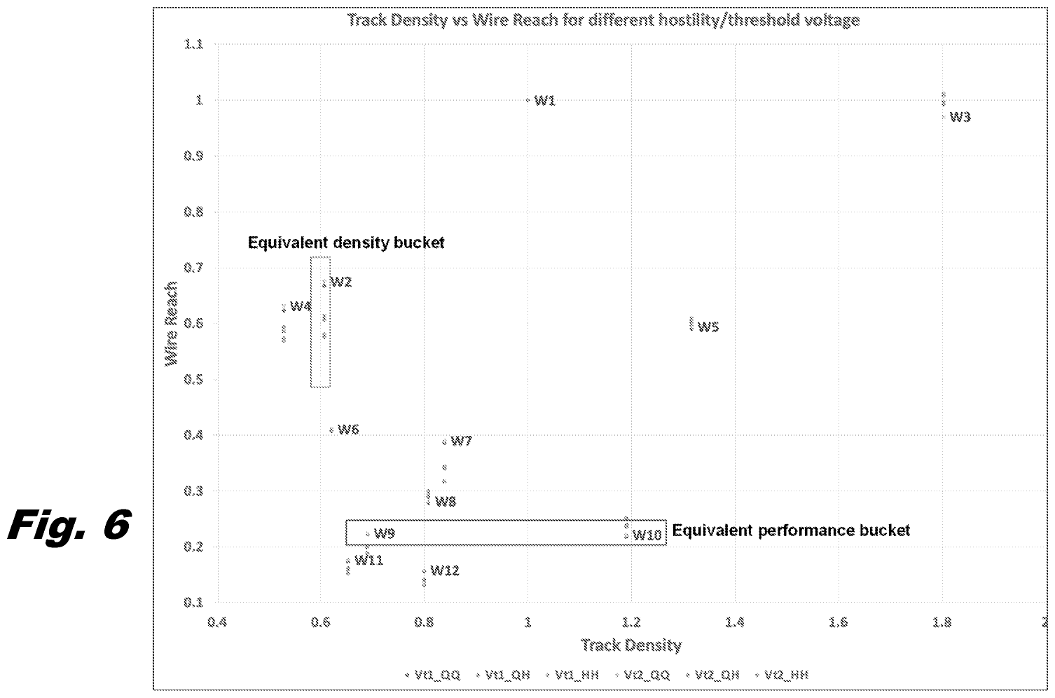

FIG. 6 is a chart further illustrating the determining of sets or buckets of equivalent wire codes. FIG. 6 illustrates that, in determining sets of equivalent wire codes, the parameters of threshold voltage and/or hostility can be taken into account.

Hostility is a term used to represent the state of switching characteristics of a net neighbouring the net under consideration. If the neighbouring net switches in the same direction as the net under consideration, it is considered ‘friendly,’ and it represents a minimum capacitance scenario. If the neighbouring net, does not switch when the net under consideration switches, it is considered ‘quiet.’ If the neighbouring net, switches in an opposite direction to the net under consideration, it is considered hostile because it represents a maximum capacitance scenario. Since there may be nets on either side of the net under consideration (i.e two neighbours), hostility is represented with a two characters code: e.g Q-H represents, one neighbour is hostile, while the other is quiet.

In an example, nets that all have a Q-Q hostility tag have wire codes that can be considered equivalent. In another example, nets that have at least one hostile neighbour (H-H and Q-H) can be grouped as equivalent. Thus, nets that might otherwise establish equivalent wire codes based on reach or density may not be equivalent if their hostility tags don't match, e.g., Q-Q v. H-H.

In other words, within a set of equivalent wire codes, the hostility tags limit which wire codes can be considered equivalent. Even though the wire codes are in the same equivalency set, the routing tool selects a new wire code from within the equivalency set based on matching the hostility tag of the net currently being routed.

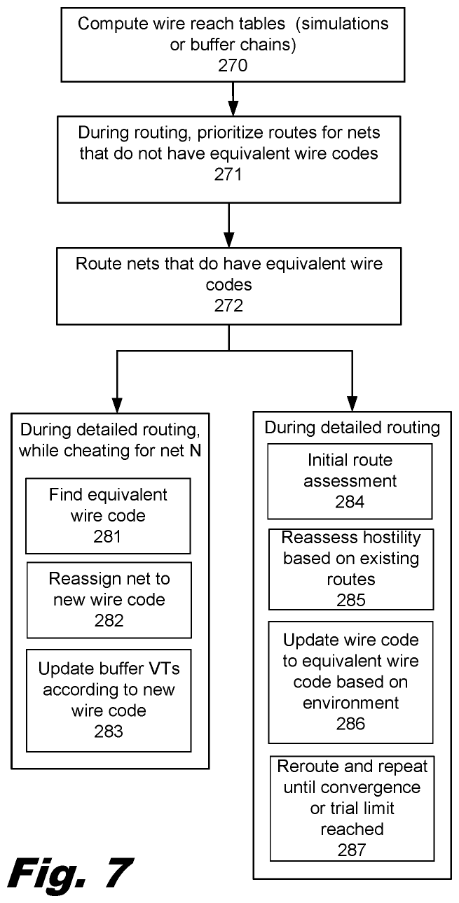

FIG. 7 is another flowchart depicting the operation of a routing tool making use of sets or buckets of equivalent wire codes according to another example of the principles described herein. As shown in FIG. 7, wire reach is computed based on the reach tables 270, as described above. Then, during routing, the routing tool will prioritize routes 271 for nets with a wire code that does not have any established equivalents. For these nets, there is no option to try an equivalent wire code if the initial attempt at routing fails. Given this lack of flexibility, routes for these nets are prioritized or placed before routes for nets with wire codes that do have established equivalents. Next, nets with wire codes among the sets of equivalent wire codes are routed by the routing tool. 272.

Here, there are two different scenarios for the routing tool. First, during detailed routing with some cheating for a particular net (N), the routing tool performs as follows. Assuming a failed routing attempt, an equivalent wire code is found 281. The net (N) is reassigned to the new wire code 282. The routing tool then updates buffer voltage thresholds according to the new wire code 283. The routing tool then attempts to route the net (N) under the new parameters as described above.

In the alternative scenario, the routing tool will perform an initial route assessment 284. If needed, there is a reassessment of hostility 285 based on the existing routes. The routing tool then updated the net wire code to an equivalent code based on the environment 286. Routing is then attempted again 287. This can be repeated until convergence (successful routing) or a limit on the trials is reached 287.

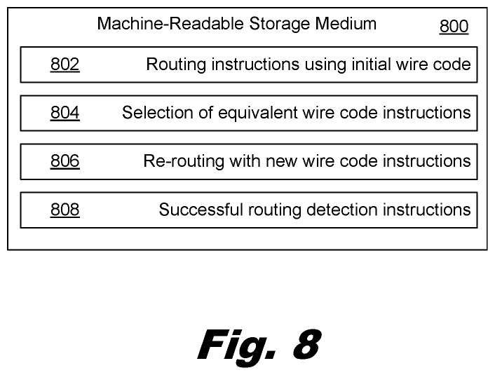

FIG. 8 is a chart depicting a computer program product of the new routing tool that makes use of sets or buckets of equivalent wire codes according to an example of the principles described herein. As shown in FIG. 8, a non-transitory machine-readable storage medium stores instructions for a routing tool, as described herein. This includes instructions for attempting routing of a net using an initial wire code assignment 802. There are also instructions for selection of an equivalent wire code 804 and re-routing or re-attempting to route the net under the new wire code 806. Lastly, there are instructions for detecting when a routing has been successful 808 under the original or new wire code.

What is claimed is:

1. A routing tool for routing nets within an integrated circuit design, the routing tool comprising:
a processor; and
a memory in communication with the processor and storing programming for the routing tool and a number of sets of equivalent wire codes;
wherein, when the processor, alone or working with other processors, executes the programming, the routing tool routes each net in the integrated circuit design to satisfy parameters specified by a wire code associated with each net;
wherein, upon failure to route a net based on a current wire code assignment, the routing tool attempts to route the net using another wire code from a set of equivalent wire codes that includes the current wire code.

2. The routing tool of claim 1, wherein one of the sets of equivalent wire codes includes wire codes with a reach within a specific tolerance but having varying track densities.

3. The routing tool of claim 1, wherein one of the sets of equivalent wire codes includes wire codes with a track density within a specific tolerance but having varying reaches.

4. The routing tool of claim 1, wherein the routing tool attempts to route the net using each wire code from the set of equivalent wire codes that includes the current wire code until the net is successfully routed.

5. The routing tool of claim 1, wherein the routing tool attempts to route the net using different wire codes from the set of equivalent wire codes until a maximum trials limit is reached.

6. The routing tool of claim 1, wherein the routing tool selects a wire code from the set of equivalent wire codes for the net based on hostility.

7. The routing tool of claim 1, wherein the routing tool prioritizes routes for nets with an assigned wire code where the assigned wire code does not have any equivalent wire codes as specified by number of sets of equivalent wire codes.

8. The routing tool of claim 1, wherein the routing tool, after assigning a new wire code to the net, updates buffer voltage thresholds according to the new wire code.

9. A method of routing nets within an integrated circuit design process, the method comprising:
for a number of wire codes, computing a reach based on reach tables;
for the number of wire codes, computing a track density; and
based on the reach and track density of each wire code, sorting the wire codes into a number of sets of equivalent wire codes, wherein a set of equivalent wire codes includes wire codes having a reach or track density that is within a certain corresponding tolerance;
wherein the number of sets of equivalent wire codes allows a routing tool additional options in routing a net according to any of the equivalent wire codes associated with a wire code of that net to produce a successful routing of the nets.

10. The method of claim 9, wherein one of the sets of equivalent wire codes includes wire codes with a reach within a specific tolerance but having varying track densities.

11. The method of claim 9, wherein one of the sets of equivalent wire codes includes wire codes with a track density within a specific tolerance but having varying reaches.

12. The method of claim 9, wherein the routing tool attempts to route the net using each wire code from the set of equivalent wire codes that includes a current wire code of the net until the net is successfully routed.

13. The method of claim 9, wherein the routing tool selects a wire code from a set of equivalent wire codes for the net based on hostility.

14. The method of claim 9, wherein the routing tool prioritizes routes for nets with an assigned wire code where the assigned wire code does not have any equivalent wire codes as specified by number of sets of equivalent wire codes.

15. The method of claim 9, wherein the routing tool, after assigning a new wire code to the net, updates buffer voltage thresholds according to the new wire code.

16. A computer program product comprising a non-transitory machine-readable storage medium incorporating instructions for a routing tool of an integrated circuit design system, the instructions comprising:
routing instructions for routing a net of an integrated circuit design using an initial wire code;
instructions for selecting an equivalent wire code based on failure to route a net using the initial wire code;
instructions for re-routing the net using the equivalent wire code; and
instructions for detecting a successful routing of the net that satisfies criteria of either the initial wire code or the equivalent wire code.

17. The product of claim 16, wherein one set of equivalent wire codes includes wire codes with a reach within a specific tolerance but having varying track densities.

18. The product of claim 16, wherein one set of equivalent wire codes includes wire codes with a track density within a specific tolerance but having varying reaches.

19. The product of claim 16, wherein the routing tool attempts to route the net using each wire code from a set of equivalent wire codes.

20. The product of claim 16, wherein the routing tool prioritizes routes for nets with an assigned wire code where the assigned wire code does not have any specified equivalent wire codes.
